(19) United States
(12) Patent Application Publication
(10) Pub. No.: US 2016/0183386 A1
(43) Pub. Date: Jun. 23, 2016

(54) TECHNIQUES FOR CONTROLLING EQUIVALENT SERIES RESISTANCE OF A CAPACITOR

(71) Applicant: QUALCOMM Incorporated, San Diego, CA (US)

(72) Inventors: Young Kyu SONG, San Diego, CA (US); Layal ROUHANA, San Diego, CA (US); Kyu-Pyung HWANG, San Diego, CA (US); Omar James BCHIR, San Marcos, CA (US)

(21) Appl. No.: 14/617,864

(22) Filed: Feb. 9, 2015

Related U.S. Application Data
(60) Provisional application No. 62/094,931, filed on Dec. 19, 2014.

(51) Int. Cl. H05K 3/46; H05K 3/32; H05K 1/11; H05K 1/18; H05K 1/02

(52) U.S. Cl. CPC H05K 3/4644; H05K 1/181; H05K 1/0298; H05K 1/115; H05K 1/111; H05K 3/4697; H05K 3/321; H05K 2201/10015

(57) ABSTRACT

Methods and apparatus for controlling an equivalent-series resistance (ESR) of a capacitor are provided. An exemplary apparatus includes a substrate having a land side, the capacitor mounted on the land side of the substrate and having both the ESR and terminals, a resistive pattern coupled to the terminals, and a plurality of vias coupled to the resistive pattern. The resistive pattern is configured to control the ESR. The resistive pattern can be formed of a resistive paste. The resistive pattern can be formed in a substantially semicircular shape having an arc ranging from substantially 45 degrees to substantially 135 degrees. The capacitor can be a surface mount device. The resistive pattern can be formed in a shape of a land-side capacitor mounting pad, a via, or both.

### CLAIM OF PRIORITY UNDER 35 U.S.C. §119

The present application for Patent claims priority to U.S. Provisional Patent Application No. 62/094,931 entitled “TECHNIQUES FOR CONTROLLING EQUIVALENT SERIES RESISTANCE OF A CAPACITOR” filed Dec. 19, 2014, and assigned to the assignee hereof and hereby expressly incorporated by reference herein in its entirety.

### INTRODUCTION

This disclosure relates generally to electronics, and more specifically, but not exclusively, to methods, apparatuses, and articles of manufacture that control an equivalent-series resistance of a capacitor.

As a result of on-going research and development, a size of transistors making up a integrated circuits (ICs) is ever-decreasing. As the transistors are made smaller, voltages supplied to the transistors also decrease. These voltages are commonly smaller than wall outlet voltages available in most countries.

Thus, an integrated circuit is commonly coupled to a voltage regulator that converts an available wall outlet voltage to the lower target operating voltage used by the integrated circuit. The voltage regulator ensures a predictable power supply is provided to the integrated circuit. This is an important function, because the ability of transistors cannot tolerate excessive voltage variations under or over the target operating voltage. Sometimes, only tenths of a volt lower than the target operating voltage can create erratic results by the integrated circuits; similarly, only tenths of a volt higher than the target operating voltage can damage the integrated circuit.

As transistors in the IC turn on and off, the power load of the IC changes rapidly, placing additional demand on the voltage regulator. The distance between the voltage regulator and the IC creates a long response time, due to inductance in the wires between the transistors and the voltage regulator. The inductance prevents the voltage regulator from increasing power to the integrated circuit instantaneously, especially when the transistors switch on and off millions, or even billions, of times per second. As the voltage regulator attempts to respond, ringing (or bouncing) can occur. These detrimental effects can be mitigated by using a decoupling capacitor to provide additional stability to the power supplied to the IC.

Decoupling capacitors are attached in close proximity to the IC provide a charge reservoir for the IC. As demand on the power supply changes rapidly, the decoupling capacitor provides additional power and can recharge at a later time when the power demand has decreased. Thus, the decoupling capacitor allows the IC to operate at high frequencies and high computational speeds demanded by consumers. However, as the transistor sizes have decreased and transistor densities have increased, finding space in the IC for the decoupling capacitor has become difficult.

One conventional configuration places the decoupling capacitor directly on the IC's die. This configuration occupies die area that could otherwise be used for active circuitry. Additionally, fabricating the decoupling capacitor requires additional fabrication processes that increase the cost of manufacturing the IC.

An alternative configuration of decoupling the IC uses surface mount capacitors on a land side of the IC's packaging substrate. The land side of the packaging substrate is the side populated by connectors for coupling to external circuits. Thus, placing the surface mount capacitors on the land side does not consume active areas of the semiconductor die.

However, conventional packaging techniques do not permit controlling equivalent series resistance of the land side capacitor on the IC's packaging substrate. To compensate for the presence of the land side capacitor, and thus control the equivalent series resistance of the land side capacitor, conventional equivalent series resistance control techniques use multiple numbers of equivalent series resistance-controlled capacitors on a circuit board to which the IC is mounted. These conventional techniques are costly and occupy circuit board space that could otherwise be used for active circuitry.

Accordingly, there are long-felt industry needs for methods and apparatus that improve upon conventional methods and apparatus, including the provided improved methods and improved apparatus.

### SUMMARY

This summary provides a basic understanding of some aspects of the present teachings. This summary is not exhaustive in detail, and is neither intended to identify all critical features, nor intended to limit the scope of the claims.

Exemplary methods, apparatuses, and articles of manufacture for controlling an equivalent-series resistance of a capacitor are provided. In an example, an apparatus includes a substrate having a land side, a capacitor mounted on the land side of the substrate and having an equivalent series resistance (ESR) and terminals, a resistive pattern coupled to the terminals, and a plurality of vias coupled to the resistive pattern. The resistive pattern is configured to control the ESR. In an example, the resistive pattern is formed of a resistive paste. In an example, the resistive pattern is formed in a substantially semicircular shape having an arc ranging from substantially 45 degrees to substantially 135 degrees. In an example, the resistive pattern is formed in a substantially semicircular shape that is substantially centered on an axis and varies in cross-section along a radius extending from the axis. In an example, the resistive pattern has a substantially right-angle bend. In an example, the resistive pattern is formed in a shape of a land-side capacitor mounting pad, a via, or both. In an example, the capacitor includes at least one electrically conductive mounting pad, electrically conductive pin, or electrically conductive ball. In an example, the capacitor is a surface mount device. In an example, the apparatus further includes a base station of which the apparatus is a constituent part, a mobile device of which the apparatus is a constituent part, or both. At least a part of the apparatus can be integrated on a semiconductor die. In a further example, provided is a non-transitory computer-readable medium, comprising fabrication device-executable instructions stored thereon configured to cause a fabrication device to fabricate at least a part of the apparatus.

In another example, provided is a method for fabricating a capacitor pad formed of conductive paste. The method includes forming a via in a substrate, forming a patterned resist layer on the via, removing a portion of the patterned resist layer adjacent to the via to define a cavity adjacent to the via, at least partially filling the cavity with the conductive paste, and mounting an electrical contact of a capacitor to the conductive paste. In an example, the conductive paste is formed in a substantially semicircular shape having an arc ranging from substantially 45 degrees to substantially 135 degrees. In an example, the conductive paste is formed in a substantially semicircular shape that is substantially centered on an axis and varies in cross-section along a radius extending from the axis. In an example, the conductive paste is formed in a substantially right-angle bend. In an example, the electrical contact of the capacitor includes at least one electrically conductive mounting pad, electrically conductive pin, or electrically conductive ball. In an example, the capacitor is a surface mount device. In an example, the method further includes integrating the substrate into a base station, integrating the substrate into a mobile device, or both. In a further example, provided is a non-transitory computer-readable medium, comprising fabrication device-executable instructions stored thereon configured to cause a fabrication device to perform at least a part of the method.

In another example, provided is a method for fabricating a capacitor pad and a via. The method includes forming, on a substrate, a laminated layer including a cavity defining the via and the capacitor pad; forming a patterned resist layer on the laminated layer; at least partially filling, through the pattern in the patterned resist layer, the cavity with a conductive paste; removing the patterned resist layer; and mounting an electrical contact of a capacitor to the conductive paste. In an example, the conductive paste is formed in a substantially semicircular shape having an arc ranging from substantially 45 degrees to substantially 135 degrees. In an example, the conductive paste is formed in a substantially semicircular shape that is substantially centered on an axis and varies in cross-section along a radius extending from the axis. In an example, the conductive paste is formed in a substantially right-angle bend. In an example, the electrical contact of the capacitor includes at least one electrically conductive mounting pad, electrically conductive pin, or electrically conductive ball. In an example, the capacitor is a surface mount device. In an example, the method further includes integrating the substrate into a base station, integrating the substrate into a mobile device, or both. In a further example, provided is a non-transitory computer-readable medium, comprising fabrication device-executable instructions stored thereon configured to cause a fabrication device to perform at least a part of the method.

In another example, provided is an apparatus. The apparatus includes a substrate having a land side, a capacitor mounted on the land side of the substrate and having an equivalent series resistance (ESR) and terminals, a means for providing a resistance that is coupled to the terminals and is configured to control the ESR, and a plurality of vias coupled to the means for providing the resistance. In an example, the means for providing the resistance is formed of a resistive paste. In an example, the means for providing the resistance is formed in a substantially semicircular shape having an arc ranging from substantially 45 degrees to substantially 135 degrees. In an example, the means for providing the resistance is formed in a substantially semicircular shape that is substantially centered on an axis and varies in cross-section along a radius extending from the axis. In an example, the means for providing the resistance has a substantially right-angle bend. In an example, the means for providing the resistance is formed in a shape of a land-side capacitor mounting pad, a via, or both. In an example, the capacitor includes at least one electrically conductive mounting pad, electrically conductive pin, or electrically conductive ball. In an example, the capacitor is a surface mount device. In an example, the apparatus further includes a base station of which the substrate is a constituent part, a mobile device of which the substrate is a constituent part, or both. At least a part of the apparatus can be integrated on a semiconductor die. In a further example, provided is a non-transitory computer-readable medium, comprising fabrication device-executable instructions stored thereon configured to cause a fabrication device to fabricate at least a part of the apparatus.

In another example, provided is a non-transitory computer-readable medium, including fabrication device-executable instructions stored thereon configured to cause a fabrication device to fabricate an apparatus, where the apparatus includes a substrate having a land side, a capacitor mounted on the land side of the substrate and having an equivalent series resistance (ESR) and terminals, a resistive pattern coupled to the terminals, and a plurality of vias coupled to the resistive pattern. The resistive pattern is configured to control the ESR. In an example, the resistive pattern is formed of a resistive paste. In an example, the resistive pattern is formed in a substantially semicircular shape having an arc ranging from substantially 45 degrees to substantially 135 degrees. In an example, the resistive pattern is formed in a substantially semicircular shape that is substantially centered on an axis and varies in cross-section along a radius extending from the axis. In an example, the resistive pattern has a substantially right-angle bend. In an example, the resistive pattern is formed in a shape of a land-side capacitor mounting pad, a via, or both. In an example, the capacitor includes at least one electrically conductive mounting pad, electrically conductive pin, or electrically conductive ball. At least a part of the apparatus can be integrated on a semiconductor die.

The foregoing broadly outlines some of the features and technical advantages of the present teachings in order that the detailed description and drawings can be better understood. Additional features and advantages are also described in the detailed description. The conception and disclosed examples can be readily utilized as a basis for modifying or designing other structures for carrying out the same purposes of the present teachings. Such equivalent constructions do not depart from the technology of the teachings as set forth in the claims. The inventive features that are characteristic of the teachings, together with further objects and advantages, are better understood from the detailed description and the accompanying figures. Each of the figures is provided for the purpose of illustration and description only, and does not limit the present teachings.

### BRIEF DESCRIPTION OF THE DRAWINGS

The accompanying drawings are presented to describe examples of the present teachings, and are not limiting.

FIG. 1 depicts an exemplary apparatus that is configured to control an equivalent series resistance (ESR).

FIG. 2 depicts four examples of different arcs of a resistive pattern.

FIG. 3 depicts another exemplary apparatus that is configured to control an ESR.

FIG. 4 depicts an exemplary graph of impedance magnitude versus frequency for ESR measurements.

FIG. 5 depicts another exemplary apparatus that is configured to control an ESR.

FIG. 6 depicts another exemplary apparatus that is configured to control an ESR.

FIG. 7 depicts another exemplary apparatus that is configured to control an ESR.

FIGS. 8A-8B depict an exemplary method for fabricating an apparatus that is configured to control an ESR, where a capacitor pad is formed of resistive paste.

FIGS. 9A-9B depict an exemplary method for fabricating an apparatus that is configured to control an ESR, where the LSCs and LSC vias are filled with resistive paste.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

### Introduction

Methods and apparatus that control an equivalent-series resistance of a capacitor, such as a land side capacitor, are provided. Equivalent series resistance (ESR) is an equivalent resistance of a capacitor affected by a signal at a standardized frequency. The ESR results from a resistance of the capacitor (leads, plates, etc.) plus a leakage resistance (e.g., due to leakage current) plus a capacitive reactance (e.g., dielectric loss) of the capacitor at the standardized frequency. The standardized frequency is used because capacitive reactance varies with a frequency of a signal affecting the capacitor, as capacitive reactance stems from delayed polarization changes in the capacitor's dielectric. If a standardized frequency model is not used, then modeling the capacitor's total resistance to current flow is difficult. Accordingly, determining the capacitive reactance is important, as the capacitive reactance affects voltage drop across the capacitor and a magnitude of current flow passing through the capacitor. This in turn affects power demand of an IC to which the capacitor is coupled, and thus a design of a power distribution network (PDN) serving the IC and the capacitor. Further complicating the PDN design are effects from voltage ripple produced by a switching power supply that supplies the PDN, as the voltage ripple varies the frequency-dependent capacitive reactance of the capacitor.

At least one of the exemplary apparatuses and/or exemplary methods disclosed herein advantageously mitigates these concerns and/or addresses the long-felt industry needs, as well as other previously unidentified needs, and mitigates shortcomings of the conventional methods and the conventional apparatus. For example, an advantage provided by at least one example of the disclosed apparatuses and/or at least one example of the methods disclosed herein is an improvement, over conventional devices, in PDN performance (e.g., reducing voltage ripple). Also, an advantage provided by at least one example of the apparatuses and/or at least one example of the methods disclosed herein is that the techniques enable controlling ESR of a capacitor without adding an additional resistor lumped component, depopulating a ball from an IC package, and/or an additional design rule. Further, an advantage provided by at least one example of the apparatuses and/or at least one example of the methods disclosed herein is that the techniques can tightly control variations (including process variations) of a resistance configured to control ESR of a capacitor. Moreover, at least one example of the apparatuses disclosed herein can easily be employed in a flip-chip chip-scale package and/or a flip-chip ball-grid array package. As another example, an advantage provided by at least one example of the disclosed apparatuses and/or at least one example of the methods disclosed herein is a reduction in impedance peaking in a PDN without changing a process of record land-side component.

Examples are disclosed in this application's text and drawings. Alternate examples can be devised without departing from the scope of the disclosure. Additionally, conventional elements of the current teachings may not be described in detail, or may be omitted, to avoid obscuring aspects of the current teachings.

### Abbreviations and Terminology

The following list of exemplary abbreviations, exemplary acronyms, and exemplary terms is provided to assist in comprehending the current disclosure, and does not limit the scope of this disclosure or the scope of the claims.
Al—Aluminum
BGA—ball grid array
Cu—copper
DER—dry film resist
ESR—equivalent series resistance
eWLB—embedded wafer ball grid array
FCBGA—flip-chip ball-grid array
FCCSP—flip-chip chip-scale package
FCLGA—flip chip land grid array
IC—integrated circuit
Land side—an underside of an IC package (for example, a side of an IC package via by which at least one electrical contact, such as a ball or pin, can couple the IC's die to a socket and/or a circuit board)
LSC—land side capacitor (for example, a capacitor attached on a land side of an IC package)
PDN—power delivery network
POR—plan of record
PPG—polypropylene glycol
PTH—plated through-hole
SAP—semi-additive process
mSAP—modified semi-additive process
SMT—surface mount
Sn—tin
SR—solder resist

As used herein, the term “exemplary” means “serving as an example, instance, or illustration.” Any example described as “exemplary” is not necessarily to be construed as preferred or advantageous over other examples. Likewise, the term “examples” does not require that all examples include the discussed feature, advantage, or mode of operation. Use of the terms “in one example,” “an example,” “in one feature,” and/or “a feature” in this specification does not necessarily refer to the same feature and/or example. Furthermore, a particular feature and/or structure can be combined with one or more other features and/or structures. Moreover, at least a portion of the apparatus described hereby can be configured to perform at least a portion of a method described hereby.

It should be noted that the terms “connected,” “coupled,” and any variant thereof, mean any connection or coupling between elements, either direct or indirect, and can encompass a presence of an intermediate element between two elements that are “connected” or “coupled” together via the intermediate element. Coupling and connection between the elements can be physical, logical, or a combination thereof. Elements can be “connected” or “coupled” together, for example, by using one or more wires, cables, printed electrical connections, electromagnetic energy, and the like. The electromagnetic energy can have a wavelength at a radio frequency, a microwave frequency, a visible optical frequency, an invisible optical frequency, and the like, as practicable. These are several non-limiting and non-exhaustive examples.

The term “signal” can include any signal such as a data signal, an audio signal, a video signal, a multimedia signal, an analog signal, a digital signal, and the like. Information and signals described herein can be represented using any of a variety of different technologies and techniques. For example, data, an instruction, a process step, a command, information, a signal, a bit, a symbol, and the like that are references herein can be represented by a voltage, a current, an electromagnetic wave, a magnetic field, a magnetic particle, an optical field, and optical particle, and/or any practical combination thereof, depending at least in part on the particular application, at least in part on the desired design, at least in part on the corresponding technology, and/or at least in part on like factors.

A reference using a designation such as “first,” “second,” and so forth does not limit either the quantity or the order of those elements. Rather, these designations are used as a convenient method of distinguishing between two or more elements or instances of an element. Thus, a reference to first and second elements does not mean that only two elements can be employed, or that the first element must necessarily precede the second element. Also, unless stated otherwise, a set of elements can comprise one or more elements. In addition, terminology of the form “at least one of: A, B, or C” or “one or more of A, B, or C” or “at least one of the group consisting of A, B, and C” used in the description or the claims can be interpreted as “A or B or C or any combination of these elements.” For example, this terminology can include A, or B, or C, or A and B, or A and C, or A and B and C, or 2A, or 2B, or 2C, and so on.

The terminology used herein is for the purpose of describing particular examples only and is not intended to be limiting. As used herein, the singular forms “a,” “an,” and “the” include the plural forms as well, unless the context clearly indicates otherwise. Further, the terms “comprises,” “comprising,” “includes,” and “including,” specify a presence of a feature, an integer, a step, an operation, an element, a component, and the like, but do not necessarily preclude a presence or an addition of another feature, integer, step, operation, element, component, and the like.

Spatial descriptions (e.g., “top,” “middle,” “bottom,” “left,” “center,” “right,” “up,” “down,” “vertical,” “horizontal,” etc.) used herein are for illustrative purposes only, and are not limiting descriptors. Practical implementations of the structures described hereby can be spatially arranged in any practicable orientation providing the functions described hereby. In addition, in using the term “adjacent” herein to describe a spatial relationship between integrated circuit elements, the adjacent integrated circuit elements need not be in direct physical contact, and other integrated circuit elements can be located between the adjacent integrated circuit elements.

In at least one example, the provided apparatuses can be a part of, and/or coupled to, an electronic device such as, but not limited to, at least one of a mobile device, a base station, a navigation device (e.g., a global positioning system receiver), a wireless device, a camera, an audio player, a camcorder, and/or a game console.

The term “mobile device” can describe, and is not limited to, at least one of a mobile phone, a mobile communication device, a pager, a personal digital assistant, a personal information manager, a personal data assistant, a mobile hand-held computer, a portable computer, a tablet computer, a wireless device, a wireless modem, other types of portable electronic devices typically carried by a person and having communication capabilities (e.g., wireless, cellular, infrared, short-range radio, etc.), and/or any other device that is capable of receiving wireless communication signals. Further, the terms “user equipment” (UE), “mobile terminal,” “user device,” “mobile device,” and “wireless device” can be interchangeable.

### DESCRIPTION OF THE FIGURES

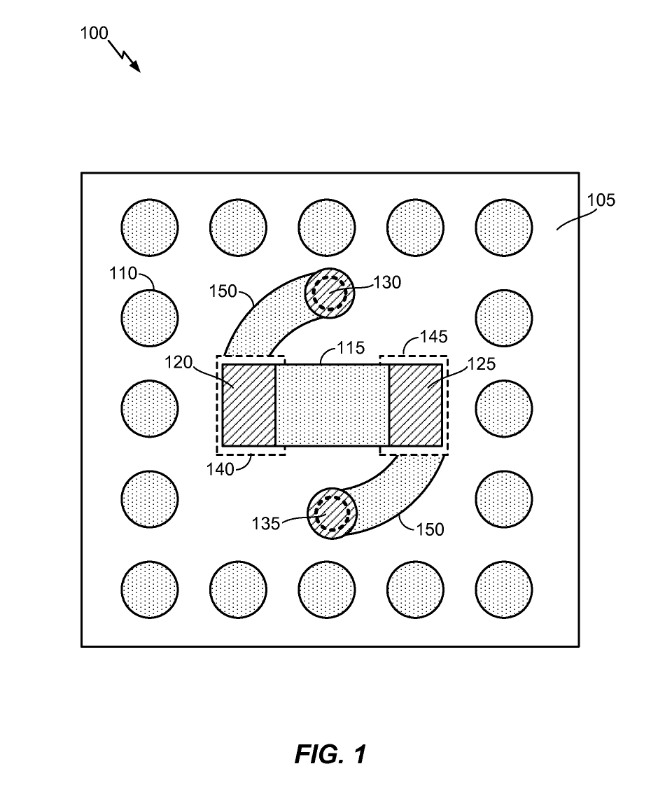

FIG. 1 depicts an exemplary apparatus 100 that is configured to control an equivalent series resistance (ESR). FIG. 1 depicts a side (e.g., a land side) of an integrated circuit (IC) package substrate 105 upon which an IC die can be mounted. The IC package substrate 105 includes electrical contacts, such as the depicted electrically-conductive balls 110 that can couple circuits on the IC's die to a circuit board. In an alternative configuration, the electrically-conductive balls 110 are replaced with electrically-conductive pins that can couple circuits on the IC's die to a circuit board and/or a socket.

In an example, a portion of the land side of the IC package substrate 105 includes a capacitor, for example a land side capacitor (LSC) 115 mounted on the land side of IC package substrate 105. The LSC has a first terminal 120 and a second terminal 125 that are electrically coupled to respective vias 130, 135 with pads 140, 145 and a resistive pattern 150. In FIG. 1, the vias 130, 135 are depicted as perpendicular to the land side of IC package substrate 105. The LSC 115 can be mounted in a plane that is substantially parallel planar with a plane of the IC package substrate 105 and includes at least one of the depicted electrically-conductive balls 110, an electrically conductive mounting pad, and/or an electrically conductive pin. In an example, the capacitor shown as LSC 115 is a surface-mount technology (SMT) capacitor.

In an example, a portion of the land side of the IC package substrate 105 is depopulated of electrical contacts to provide space for the LSC 115. In FIG. 1, the depopulated portion replaces the space of a 3×3 array of electrical contacts. The depopulated portion depicted in FIG. 1 is illustrative, and does not limit the scope of this disclosure or the scope of the claims.

The resistive pattern 150 is coupled in series with the LSC 115 and controls (i.e., mitigates) the ESR of the LSC 115 by providing a dampening resistance to a power distribution network supplying power to the IC die. To provide the dampening resistance, the resistive pattern is fabricated of a material having a known resistance per unit of area (i.e., sheet resistivity), such as a resistive paste containing materials such as carbon, silver, aluminum, adhesives, and binding agents. The resistive paste can have a resistivity higher than that of copper.

The shape and volume of the resistive pattern 150 provides variability of the provided dampening resistance, such that the dampening resistance can be matched to the LSC 115. The resistive pattern 150 can have a variety of shapes, such as a substantially right-angle bend. FIG. 1 depicts the resistive pattern 150 is formed in a substantially semicircular shape that is substantially centered on an axis. The substantially semicircular shape of the resistive pattern 150 can have an arc ranging from substantially zero degrees to substantially 135 degrees. The resistive pattern 150 is an example of a means for providing a resistance.

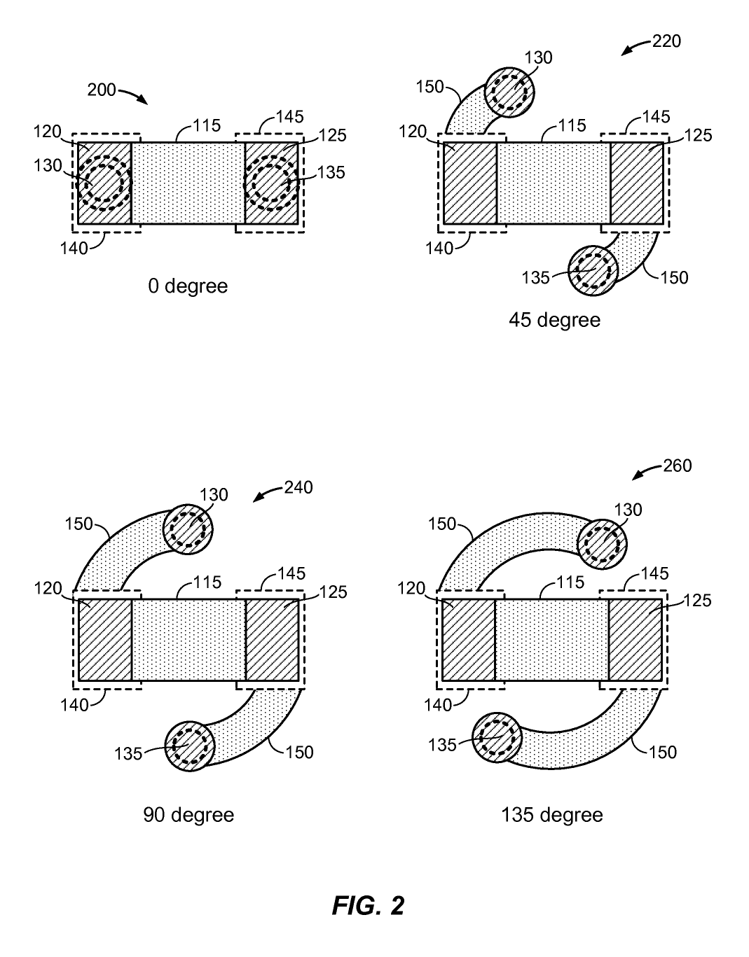

FIG. 2 depicts four examples 200, 220, 240, 260 of different arcs of the resistive pattern 150. In the first example 200, the arc of the resistive pattern 150 is substantially zero degrees. In other words, the resistive pattern 150 is located in a stack between the first terminal 120, the second terminal 125, and the pads 140, 145. In an example, at least one of the via 130, the via 135, the pad 140, the pad 145, or a combination thereof can be at least a portion of the resistive pattern 150.

In the second example 220, the arc of the resistive pattern 150 is substantially 45 degrees. In the second example 220, the resistive pattern 150 has a longer arc than the resistive pattern 150 of the first example 200. Thus, when the sheet resistance of the resistive pattern 150 is the same in the first example 200 and the second example 220, the resistive pattern 150 of the second example 220 has a higher resistance than the resistive pattern 150 of the first example 200.

In the third example 240, the arc of the resistive pattern 150 is substantially 90 degrees. In the fourth example 260, the arc of the resistive pattern 150 is substantially 135 degrees.

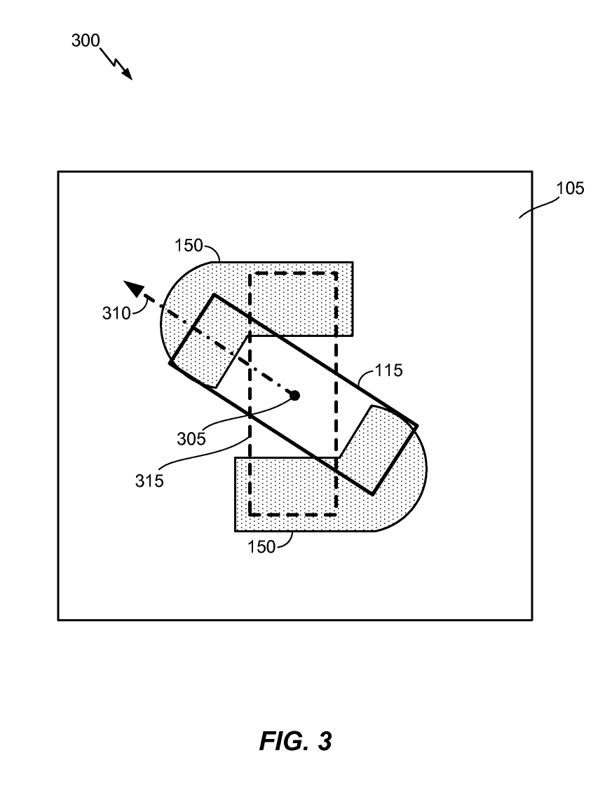

In another exemplary apparatus 300 depicted in FIG. 3, the resistive pattern 150 is substantially centered about an axis 305 and the resistive pattern 150 varies in cross-section along a radius 310 extending from the axis 305. The shape of the resistive pattern 150 depicted in FIG. 3 is an example, and does not limit the scope of this disclosure or the scope of the claims. In examples, the resistive pattern 150 can have a shape different from that depicted in FIG. 3. The LSC 115 can be coupled to the resistive pattern 150 at any practicable angle substantially about the axis 305. Thus, the resistive pattern 150 as depicted in FIG. 3 can provide a variety of different dampening resistances, with the provided dampening resistance being dependent upon the angle at which the LSC 115 is mounted relative to the resistive pattern 150. For example, in FIG. 3, dashed lines depict an alternate mounting location 315 of the LSC 115 relative to the resistive pattern 150. The alternate mounting location 315 is an example, and does not limit the scope of this disclosure or the scope of the claims.

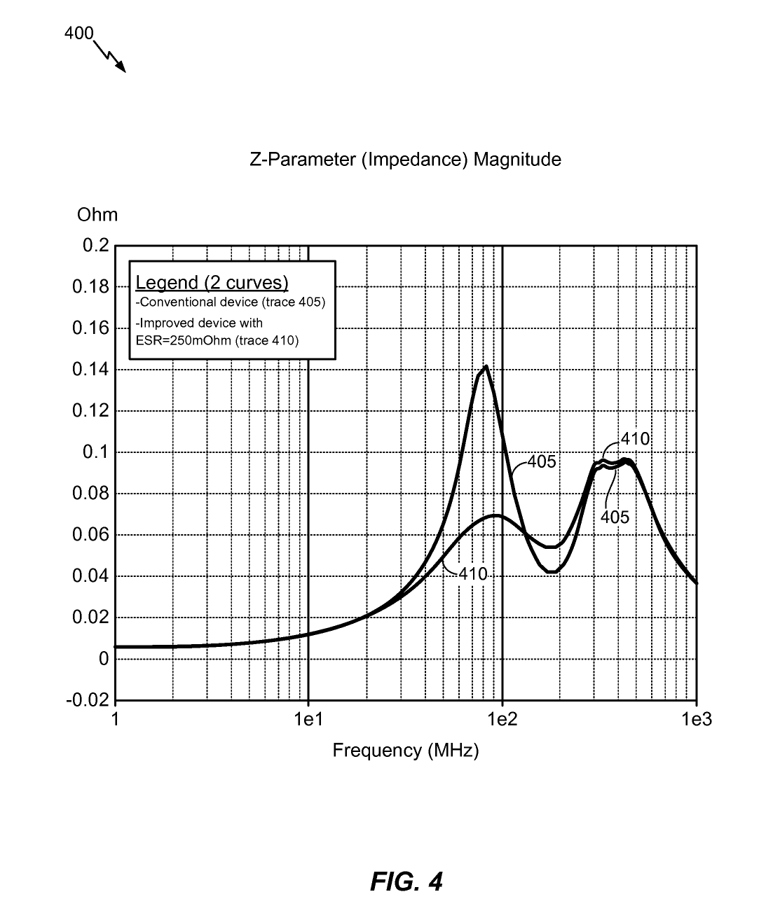

FIG. 4 depicts an exemplary graph 400 of impedance magnitude (Y-axis) versus frequency (X-axis) for two ESR measurements. The first trace 405 depicts an intrinsic ESR of a test circuit including and LSC, and without using the techniques disclosed herein. The second trace 410 depicts an ESR of the same LSC, but where the test circuit is modified with the disclosed ESR control techniques. As can be seen from the differences in the traces, the controlled resistance of the resistive pattern 150, which in this example is about 250 mohm, provides additional ESR in series with the intrinsic ESR, which is about 30 mohm. The result is that the peak impedance of the test circuit is lower, and the second trace 410 is flatter (i.e., less variable with changes in frequency than the first trace 405). Thus, a PDN supplying the test circuit will have better performance when the test circuit is modified with the disclosed ESR control techniques.

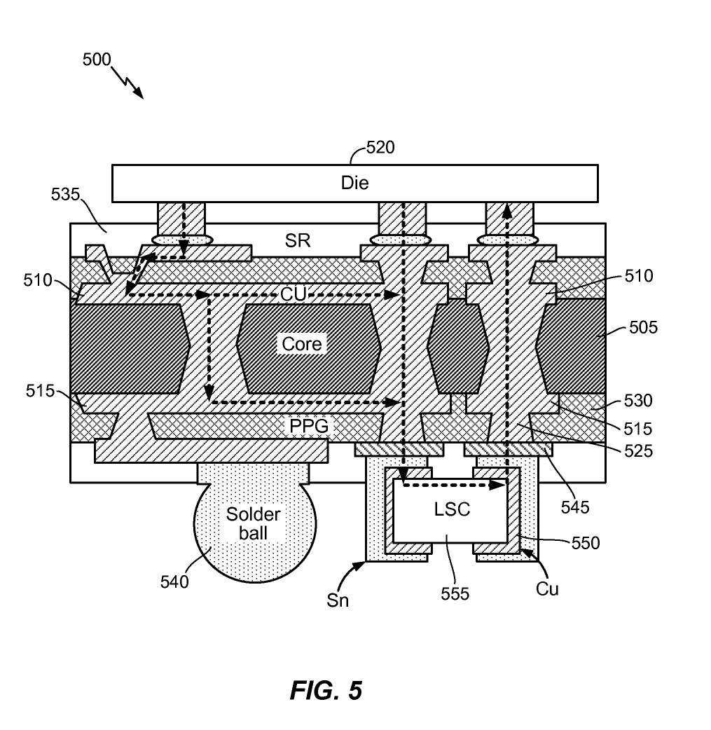

FIG. 5 depicts an exemplary apparatus 500 that is configured to control an equivalent series resistance (ESR). The ESR can advantageously be controlled on an IC package substrate. The apparatus 500 includes portions of an IC package, such as a FCBGA, FCCSP, FCLGA, and the like. The apparatus 500 includes a substrate (Core) 505 such as an IC package substrate (also known as an interposer), upon which there can be at least one optional redistribution layer 510, 515 formed of a conductor (e.g., Al, Cu). The redistribution layers 510, 515 electrically extend the contacts of an IC 520 to other locations on the substrate 505 (e.g., for a less dense footprint). At least one via 525 can pass through the substrate 505 or an insulating layer on the substrate, so that current can flow between different layers of the apparatus 500. The different layers of the apparatus 500 can include an insulating layer, such as a passivation layer or polymer layer (e.g., PPG 530, SR 535). The redistribution layers 510, 515 and the via 525 can electrically couple circuits on the die 520 to an electrical contact 540, such as a solder ball, pin, and/or pad that is configured to electrically couple the IC package to a circuit board and/or a socket.

The redistribution layers 510, 515 and the via 525 can electrically couple the die 520 and/or the electrical contact 540 to a pad 545 that is formed of resistive paste. The pad 545 can electrically couple to a terminal 550 of a LSC 555. The pad 545 provides a dampening resistance to a power distribution network supplying power to the IC die 520. To provide the dampening resistance, the pad 545 can be fabricated of a material, such as those described herein. In an example, the pad 545 is formed at least in part in a shape of the resistive pattern 150 in a plane that is coplanar with the substrate 505. The pad 545 is an example of a means for providing a resistance.

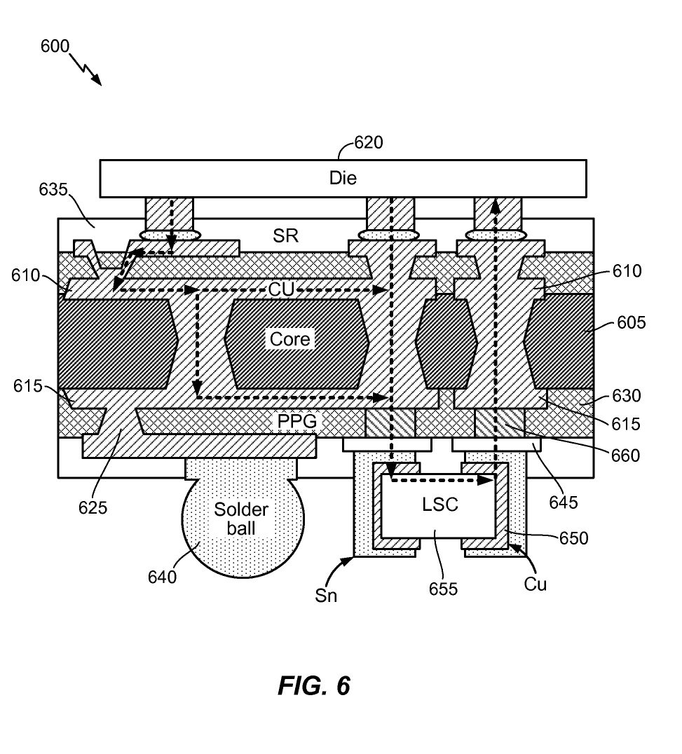

FIG. 6 depicts an exemplary apparatus 600 that is configured to control an equivalent series resistance (ESR). The ESR can advantageously be controlled on an IC package substrate. The apparatus 600 includes portions of an IC package, such as a FCBGA, FCCSP, and the like. The apparatus 600 includes a substrate (Core) 605 such as an IC package substrate (also known as an interposer), upon which there can be at least one optional redistribution layer 610, 615 formed of a conductor (e.g., Al, Cu). The redistribution layers 610, 615 electrically extend the contacts of an IC 620 to other locations on the substrate 605 (e.g., for a less dense footprint). At least one via 625 can pass through the substrate 505 or an insulating layer on the substrate, so that current can flow between different layers of the apparatus 600. The different layers of the apparatus 600 can include an insulating layer, such as a passivation layer or polymer layer (e.g., PPG 630, SR 635). The redistribution layers 610, 615 and the via 625 can electrically couple circuits on the die 620 to an electrical contact 640, such as a solder ball, pin, and/or pad that is configured to electrically couple the IC package to a circuit board and/or a socket.

In the example, of FIG. 6, the redistribution layers 610, 615, the via 625, a resistive paste via 660, or a practicable combination thereof can electrically couple the die 620 and/or the electrical contact 640 to a pad 645 that is formed of a conductor (e.g., Al, Cu). The pad 645 can electrically couple to a terminal 650 of a LSC 655. The resistive paste via 660 provides a dampening resistance to a power distribution network supplying power to the IC die 620. To provide the dampening resistance, the resistive paste via 660 can be fabricated of a material such as those described herein. The via 660 is an example of a means for providing a resistance.

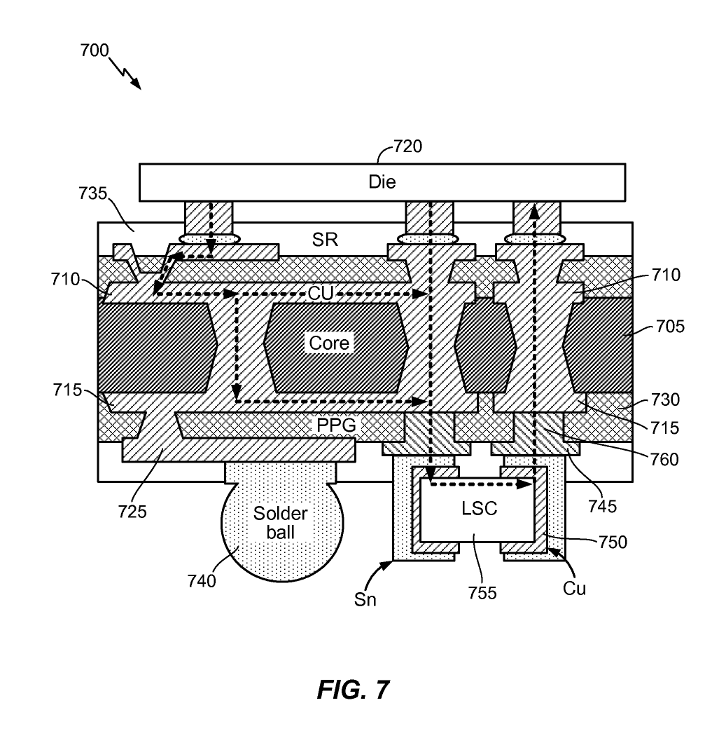

FIG. 7 depicts an exemplary apparatus 700 that is configured to control an equivalent series resistance (ESR). The ESR can advantageously be controlled on an IC package substrate. The apparatus 700 includes portions of an IC package, such as a FCBGA, FCCSP, and the like. The apparatus 700 includes a substrate (Core) 705 such as an IC package substrate (also known as an interposer), upon which there can be at least one optional redistribution layer 710, 715 formed of a conductor (e.g., Al, Cu). The redistribution layers 710, 715 electrically extend the contacts of an IC 720 to other locations on the substrate 705 (e.g., for a less dense footprint). At least one via 725 can pass through the substrate 505 or an insulating layer on the substrate, so that current can flow between different layers of the apparatus 700. The different layers of the apparatus 700 can include an insulating layer, such as a passivation layer or polymer layer (e.g., PPG 730, SR 735). The redistribution layers 710, 715 and the via 725 can electrically couple circuits on the die 720 to an electrical contact 740, such as a solder ball, pin, and/or pad that is configured to electrically couple the IC package to a circuit board and/or a socket.

In the example, of FIG. 7, the redistribution layers 710, 715, the via 725, a resistive paste via 770, or a practicable combination thereof can electrically couple the die 720 and/or the electrical contact 740 to a pad 745 that is formed of resistive paste. The pad 745 can electrically couple to a terminal 750 of a LSC 755. The resistive paste via 760 and the pad 745 provide a dampening resistance to a power distribution network supplying power to the IC die 720, which controls the ESR. To provide the dampening resistance, the resistive paste via 760 and the pad 745 can be fabricated of a material, such as those described herein. In an example, the pad 745 is formed at least in part in a shape of the resistive pattern 150 in a plane that is coplanar with the substrate 705. The pad 745 and the resistive paste via 760 are examples of means for providing a resistance.

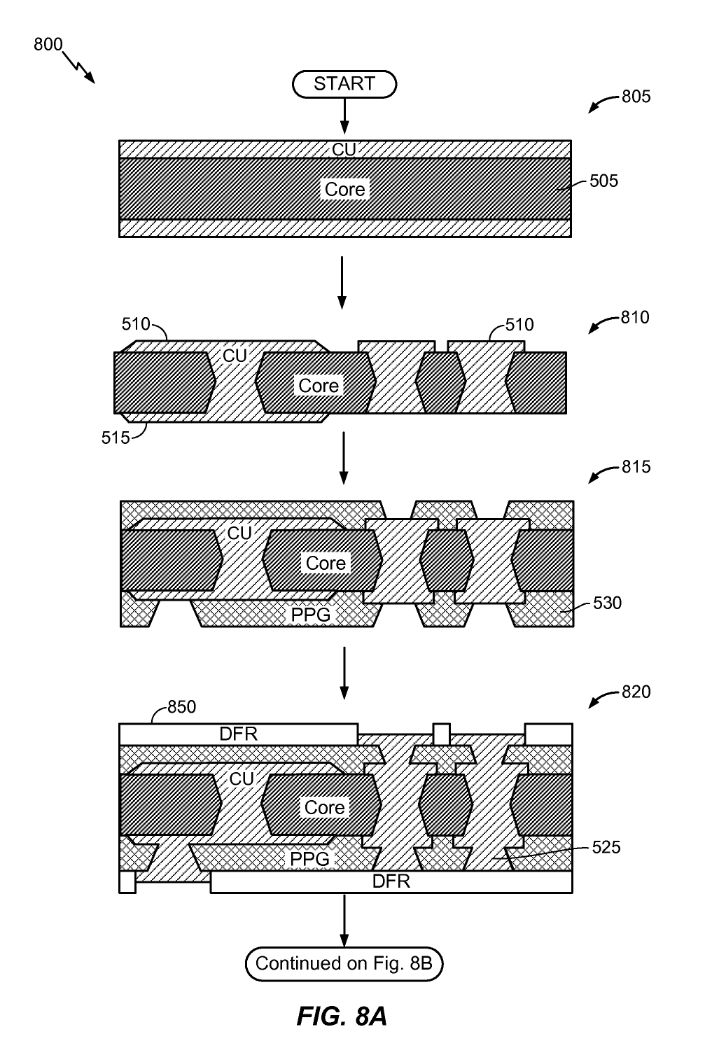

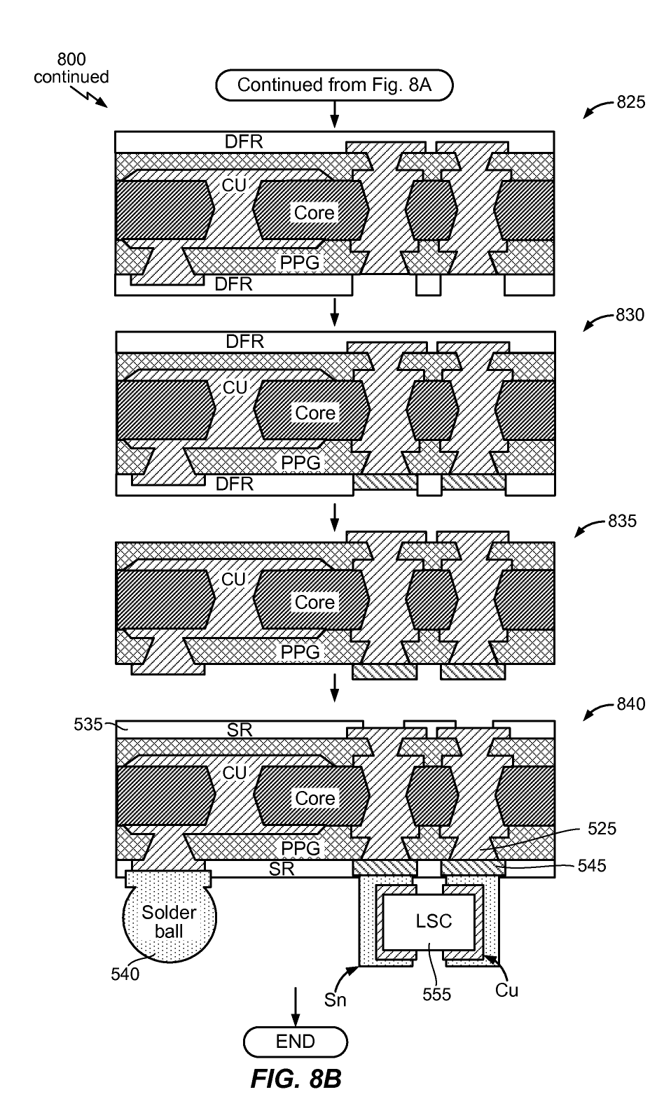

FIGS. 8A-8B depict an exemplary method 800 for fabricating an apparatus that is configured to control an equivalent series resistance (ESR), such as, for example, the apparatus 500. In the exemplary method 800, a land side capacitor pad is formed of resistive paste.

In block 805, at least one conductive layer (e.g., Cu, Al) is formed on a substrate (Core) 505. A redistribution layer, (e.g., the redistribution layers 510, 515) can subsequently be formed from the at least one conductive layer.

In block 810, the at least one conductive layer can be patterned, holes can be drilled (e.g., with a laser), and/or vias can subsequently be formed in the substrate 505 using a mSAP and/or a SAP.

In block 815, a PPG layer can be formed and outer layers can be patterned. Holes can be drilled in the PPG layer for via formation.

In block 820, a dry film resist layer (DFR) 850 is formed on the substrate 505 and patterned. Vias can be formed using the DFR 850 by depositing a conductor through a cavity defined by the patterned DFR 850. In block 820, optionally, the DFR 850 does not define a cavity with which to form the via that couples to the via 525.

In block 825, the DFR 850 is patterned to define a cavity within which a pad that can be coupled to the LSC can be formed, such as the pad 545. Optionally, a second layer of DFR 850 can be deposited prior to patterning the DFR 850 in block 825.

In block 830, the pad that can be coupled to the LSC can be formed, such as the pad 545, of resistive paste. The pad can be formed by depositing the resistive paste on the patterned DFR 850. Excess resistive paste can then be removed, for example, by squeegeeing any excess paste off of the surface of the DFR 850.

In block 835, the resistive paste is cured, if necessary, and the DFR is removed.

In block 840, the LSC (e.g., the LSC 555) is mounted on the pad formed of the resistive paste. Optionally, SR is applied as a protective layer. Also optionally, an electrical contact (e.g., the electrical contact 540), such as a solder ball, pin, and/or pad that is configured to electrically couple the IC package to a circuit board and/or a socket is formed on the substrate 505 in electrical contact with a via or a pad.

The foregoing steps are not limiting of the examples. The steps can be combined and/or the order can be rearranged, as practicable.

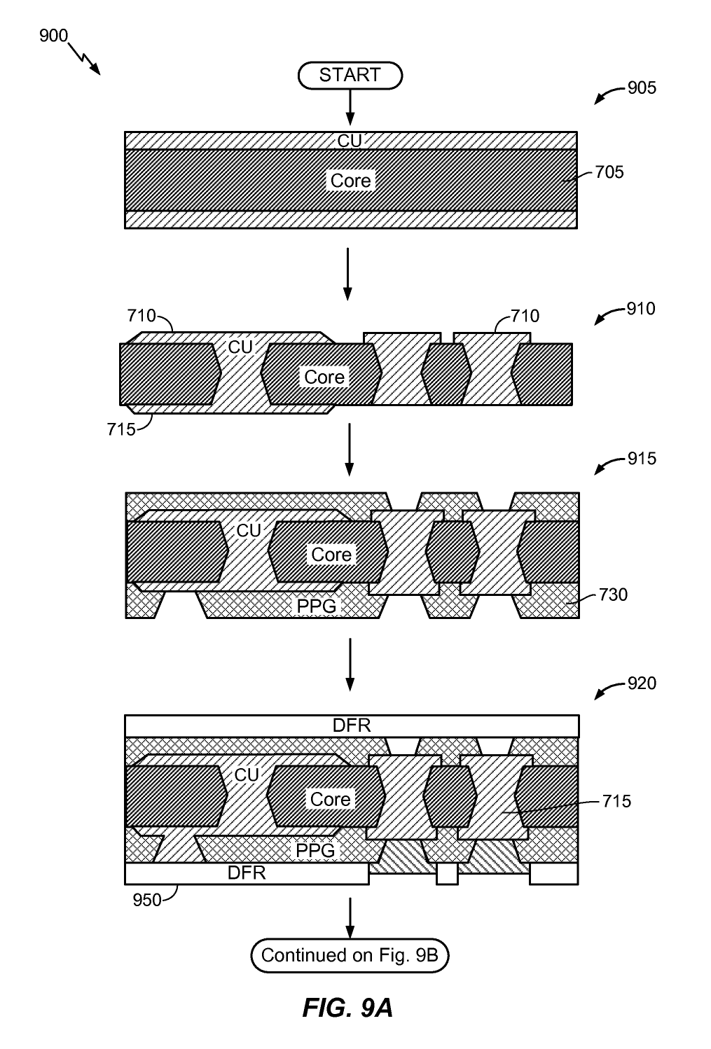

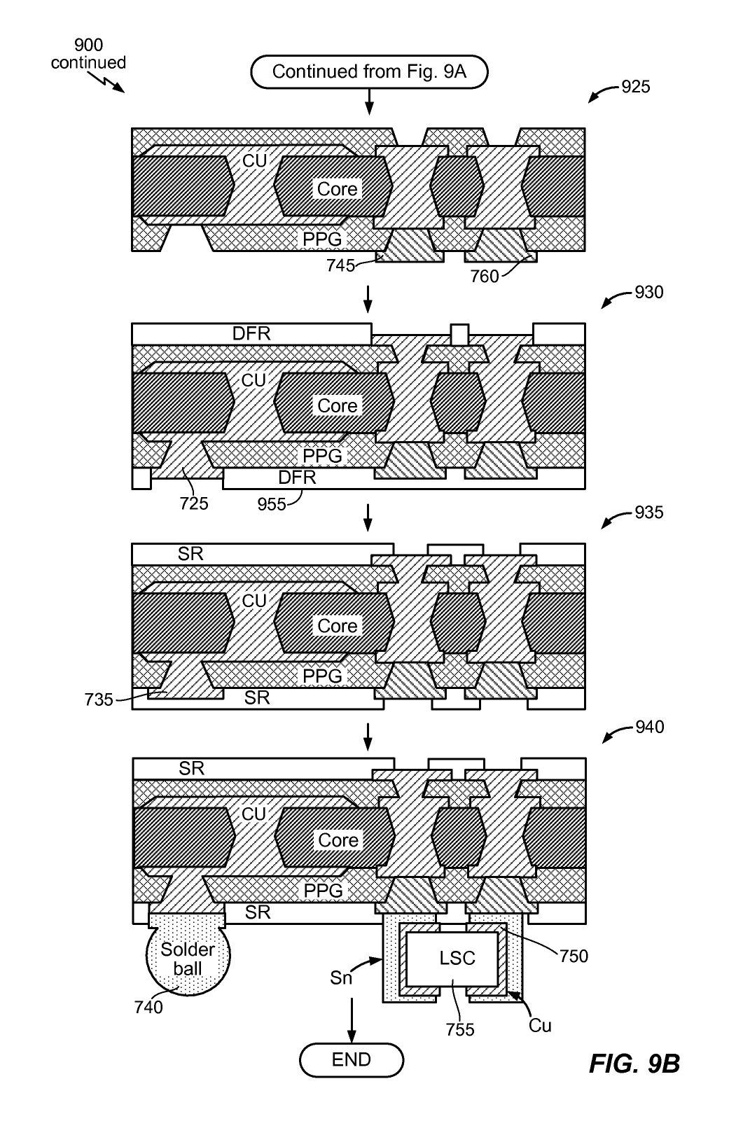

FIGS. 9A-9B depict an exemplary method 900 for fabricating an apparatus that is configured to control an equivalent series resistance (ESR), such as, for example, the apparatus 700. In the exemplary method 900, LSCs and LSC vias are filled with resistive paste.

In block 905, at least one conductive layer (e.g., Cu, Al) is formed on a substrate (Core) 705. A redistribution layer, (e.g., the redistribution layers 710, 715) can subsequently be formed from the at least one conductive layer.

In block 910, the at least one conductive layer can be patterned, holes can be drilled (e.g., with a laser), and/or vias can be formed in the substrate 705 using a mSAP and/or a SAP.

In block 915, a PPG layer can be formed and outer layers can be patterned. Holes can be drilled in the PPG layer for via formation.

In block 920, a first dry film resist layer (DFR) 950 is formed on the substrate 705 and patterned. Vias can be formed using the first DFR 950 by depositing a conductor through a cavity defined by the patterned first DFR 950. A via (e.g., the via 760) and a pad 745 can be formed by depositing the resistive paste on the patterned first DFR 950. Excess resistive paste can then be removed, for example, by squeegeeing any excess paste off of the surface of the first DFR 950.

In block 925, the first DFR 950 is removed.

In block 930, a second dry film resist layer (DFR) 955 is formed on the substrate 705 and patterned to define a cavity within which a via can be formed, such as the via 725. The via can be formed in the cavity.

In block 935, the second DFR 955 is removed and SR is applied as a protective layer.

In block 940, the LSC (e.g., the LSC 755) is mounted on the pad formed of the resistive paste (e.g., the pad 745). Optionally, SR is applied as a protective layer. Also optionally, an electrical contact (e.g., the electrical contact 740), such as a solder ball, pin, and/or pad that is configured to electrically couple the IC package to a circuit board and/or a socket is formed on the substrate 705 in electrical contact with a via or a pad.

The foregoing steps are not limiting of the examples. The steps can be combined and/or the order can be rearranged, as practicable.

Further, those of skill in the art will appreciate that the exemplary logical blocks, modules, circuits, and steps described in the examples disclosed herein may be implemented as electronic hardware, computer software, or combinations of both, as practicable. To clearly illustrate this interchangeability of hardware and software, exemplary components, blocks, modules, circuits, and steps have been described herein generally in terms of their functionality. Whether such functionality is implemented as hardware or software depends upon the particular application and design constraints imposed on an overall system. Skilled artisans can implement the described functionality in different ways for each particular application, but such implementation decisions should not be interpreted as causing a departure from the scope of the present disclosure.

At least a portion of the methods, sequences, and/or algorithms described in connection with the examples disclosed herein can be directly in hardware, in software executed by a processor, or in a combination of the two. In an example, a processor includes multiple discrete hardware components. A software module may reside in RAM memory, flash memory, ROM memory, EPROM memory, EEPROM memory, registers, hard disk, a removable disk, a CD-ROM, and/or any other form of storage medium known in the art. An exemplary storage medium (e.g., a memory) can be coupled to the processor such that the processor can read information from, and write information to, the storage medium. In an alternative, the storage medium may be integral with the processor.

Further, many examples are described in terms of sequences of actions to be performed by, for example, elements of a computing device. The actions described herein can be performed by a specific circuit (e.g., an application specific integrated circuit (ASIC)), by program instructions being executed by one or more processors, or by a combination of both. Additionally, a sequence of actions described herein can be considered to be entirely within any form of computer readable storage medium having stored therein a corresponding set of computer instructions that upon execution would cause an associated processor (such as a special-purpose processor) to perform at least a portion of a function described herein. Thus, the aspects may be in a number of different forms, all of which have been contemplated to be within the scope of the disclosure. In addition, for each of the examples described herein, a corresponding circuit of any such examples may be described herein as, for example, “logic configured to” perform a described action.

The disclosed devices and methods can be designed and can be configured into a computer-executable file that is in a Graphic Database System Two (GDSII) compatible format, an Open Artwork System Interchange Standard (OASIS) compatible format, and/or a GERBER (e.g., RS-274D, RS-274X, etc.) compatible format, which are stored on a non-transitory (i.e., a non-transient) computer-readable media. The file can be provided to a fabrication handler who fabricates with a lithographic device, based on the file, an integrated device. Deposition of a material to form at least a portion of a structure described herein can be performed using deposition techniques such as physical vapor deposition (PVD, e.g., sputtering), plasma-enhanced chemical vapor deposition (PECVD), thermal chemical vapor deposition (thermal CVD), and/or spin-coating. Etching of a material to form at least a portion of a structure described herein can be performed using etching techniques such as plasma etching. In an example, the integrated device is on a semiconductor wafer. The semiconductor wafer can be cut into a semiconductor die and packaged into a semiconductor chip. The semiconductor chip can be employed in a device described herein (e.g., a mobile device).

An example can include a non-transitory (i.e., a non-transient) machine-readable media and/or a non-transitory (i.e., a non-transient) computer-readable media storing instructions which, when executed by a processor (such as a special-purpose processor), transform a processor and any other cooperating devices into a machine (e.g., a special-purpose processor) configured to perform at least a part of a function described hereby and a method described hereby. In an example, execution of the stored instructions can transform a processor and any other cooperating devices into at least a part of the apparatus described hereby. A non-transitory (i.e., a non-transient) machine-readable media specifically excludes a transitory propagating signal.

Nothing stated or depicted in this application is intended to dedicate any component, step, feature, object, benefit, advantage, or equivalent to the public, regardless of whether the component, step, feature, object, benefit, advantage, or the equivalent is recited in the claims.

While this disclosure describes examples, changes and modifications can be made to the examples disclosed herein without departing from the scope defined by the appended claims. The present disclosure is not intended to be limited to the specifically disclosed examples alone.

What is claimed is:

1. An apparatus, comprising:
a substrate having a land side;
a capacitor mounted on the land side of the substrate and having an equivalent series resistance (ESR) and terminals;
a resistive pattern coupled to the terminals; and
a plurality of vias coupled to the resistive pattern,
wherein the resistive pattern is configured to control the ESR.

2. The apparatus of claim 1, wherein the resistive pattern is formed of a resistive paste.

3. The apparatus of claim 1, wherein the resistive pattern is formed in a substantially semicircular shape having an arc ranging from substantially 45 degrees to substantially 135 degrees.

4. The apparatus of claim 1, wherein the resistive pattern is formed in a substantially semicircular shape that is substantially centered on an axis and varies in cross-section along a radius extending from the axis.

5. The apparatus of claim 1, wherein the resistive pattern has a substantially right-angle bend.

6. The apparatus of claim 1, wherein the resistive pattern is formed in a shape of a land-side capacitor mounting pad, a via, or both.

7. The apparatus of claim 1, wherein the capacitor includes at least one electrically conductive mounting pad, electrically conductive pin, or electrically conductive ball.

8. The apparatus of claim 1, wherein the capacitor is a surface mount device.

9. The apparatus of claim 1, further comprising a base station of which the apparatus is a constituent part, a mobile device of which the apparatus is a constituent part, or both.

10. A method for fabricating a capacitor pad formed of conductive paste, comprising:
forming a via in a substrate;
forming a patterned resist layer on the via;
removing a portion of the patterned resist layer adjacent to the via to define a cavity adjacent to the via;
at least partially filling the cavity with conductive paste; and
mounting an electrical contact of a capacitor to the conductive paste.

11. The method of claim 10, wherein the conductive paste is formed in a substantially semicircular shape having an arc ranging from substantially 45 degrees to substantially 135 degrees.

12. The method of claim 10, wherein the conductive paste is formed in a substantially semicircular shape that is substantially centered on an axis and varies in cross-section along a radius extending from the axis.

13. The method of claim 10, wherein the conductive paste is formed in a substantially right-angle bend.

14. The method of claim 10, wherein the electrical contact of the capacitor includes at least one electrically conductive mounting pad, electrically conductive pin, or electrically conductive ball.

15. The method of claim 10, wherein the capacitor is a surface mount device.

16. The method of claim 10, further comprising integrating the substrate into a base station, integrating the substrate into a mobile device, or both.

17. A method for fabricating a capacitor pad and a via, comprising:
forming, on a substrate, a laminated layer including a cavity defining the via and the capacitor pad;
forming a patterned resist layer on the laminated layer, wherein the patterned resist layer has a pattern;
at least partially filling, through the pattern in the patterned resist layer, the cavity with a conductive paste;
removing the patterned resist layer; and
mounting an electrical contact of a capacitor to the conductive paste.

18. The method of claim 17, wherein the conductive paste is formed in a substantially semicircular shape having an arc ranging from substantially 45 degrees to substantially 135 degrees.

19. The method of claim 17, wherein the conductive paste is formed in a substantially semicircular shape that is substantially centered on an axis and varies in cross-section along a radius extending from the axis.

20. The method of claim 17, wherein the conductive paste is formed in a substantially right-angle bend.

21. The method of claim 17, wherein the electrical contact of the capacitor includes at least one electrically conductive mounting pad, electrically conductive pin, or electrically conductive ball.

22. The method of claim 17, wherein the capacitor is a surface mount device.

23. The method of claim 17, further comprising integrating the substrate into a base station, integrating the substrate into a mobile device, or both.

24. An apparatus, comprising:
a substrate having a land side;
a capacitor mounted on the land side of the substrate and having an equivalent series resistance (ESR) and terminals;
a means for providing a resistance, wherein the means for providing the resistance is coupled to the terminals and is configured to control the ESR; and
a plurality of vias coupled to the means for providing the resistance.

25. The apparatus of claim 24, wherein the means for providing the resistance is formed of a resistive paste.

26. The apparatus of claim 24, wherein the means for providing the resistance is formed in a substantially semicircular shape having an arc ranging from substantially 45 degrees to substantially 135 degrees.

27. The apparatus of claim 24, wherein the means for providing the resistance is formed in a substantially semicircular shape that is substantially centered on an axis and varies in cross-section along a radius extending from the axis.

28. The apparatus of claim 24, wherein the means for providing the resistance has a substantially right-angle bend.

29. The apparatus of claim 24, wherein the means for providing the resistance is formed in a shape of a land-side capacitor mounting pad, a via, or both.

30. The apparatus of claim 24, further comprising a base station of which the substrate is a constituent part, a mobile device of which the substrate is a constituent part, or both.
